(19) United States
(12) Patent Application Publication
(10) Pub. No.: US 2003/0107116 A1
(43) Pub. Date: Jun. 12, 2003

(54) WINDOWFRAME CAPACITOR

(76) Inventor: Bidyut K. Sen, Milpitas, CA (US)

Correspondence Address: ROSENTHAL & OSHA L.L.P., Suite 2800, 1221 McKinney, Houston, TX, 77010, US

(21) Appl. No.: 10/010,237

(22) Filed: Dec. 7, 2001

(51) Int. Cl. H01L 23/02

(52) U.S. Cl. 257/680

(57) ABSTRACT

A capacitor having an aperture in a central portion of the capacitor is provided. Such a “windowframe” capacitor has capacitive material disposed within a housing of the capacitor in order to provide effective capacitance and reduced inductance. Further, a semiconductor package assembly having a semiconductor die and a windowframe capacitor is provided.

### BACKGROUND OF INVENTION

FIG. 1 is a schematic side-view of a prior art package assembly for a semiconductor device. In this configuration, which is known as a “flip-chip” package, the active device, here shown as semiconductor die 11, is inverted so that the active side of the die is facing away from the package substrate 13. An advantage of this configuration is that it facilitates heat dissipation from the back of the semiconductor die 11 directly to a heat removal device such as a heat sink.

The active side of the semiconductor device in the flip-chip package is connected to the package substrate via any one of a number of conventional methods. In this example shown, the connection method is via a plurality of solder balls 14 in what is known in the industry as a ball-grid array (BGA). Other known connection mechanisms include a pin grid array (PGA), a land grid array (LGA), a plastic pin array (PPA), and a ceramic pin grid array (CPGA). Although a relatively small number of solder balls 14 are shown in the figure for purposes of illustration, in actuality there would be a much greater number of balls relative to the size of the elements shown.

It is known to use the area 12 on top of the package substrate 13 surrounding the semiconductor die 11 for use as a mounting location for high frequency capacitors. For purposes of example, two such capacitors 17 are shown in FIG. 1. These capacitors may be mounted in a BGA configuration, or by any other known connection mechanism. FIG. 2 illustrates the prior art flip-chip package assembly of FIG. 1 in top view. In this view, for the sake of example, four capacitors 17 are shown.

Prior art FIG. 3 shows a prospective view of a flip-chip package mounted in a socket 19 on a printed circuit board (PCB) 20. In this figure, the package assembly including the package substrate 13, semiconductor die 11, and capacitors 17 are shown engaged in socket 19, which in turn is mounted on PCB 20. Also mounted on PCB 20 are various typical electronic components, including, for example, low frequency capacitors 21, transistors 23, and air-core inductor 25.

### SUMMARY OF INVENTION

According to one aspect of the present invention, a windowframe capacitor comprises a housing having a bottom surface and a top surface, where an aperture is formed in a central portion thereof extending from the top surface to the bottom surface; and capacitive material disposed within the housing to create a desired amount of capacitance, where the bottom surface is provided with electrical connections adapted to be connected to a substrate.

According to another aspect, a semiconductor package assembly comprises a semiconductor die mounted on a portion of a top surface of a package substrate; and a windowframe capacitor having an aperture formed therein, and mounted on the top surface of the package substrate surrounding the semiconductor die.

Other aspects and advantages of the invention will be apparent from the following description and the appended claims.

### BRIEF DESCRIPTION OF DRAWINGS

FIG. 1 is a side view of a prior art flip-chip package assembly;

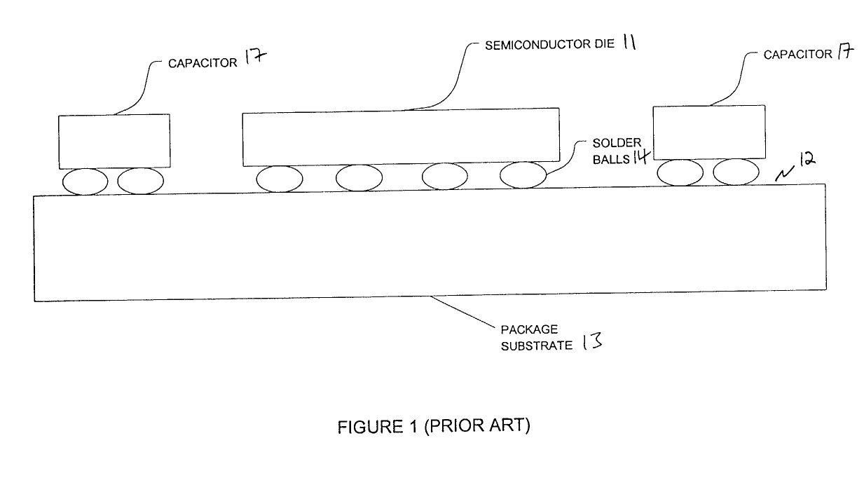

FIG. 2 is a top view of the assembly of FIG. 1;

FIG. 3 is a prospective view of a flip-chip assembly installed on a printed circuit board;

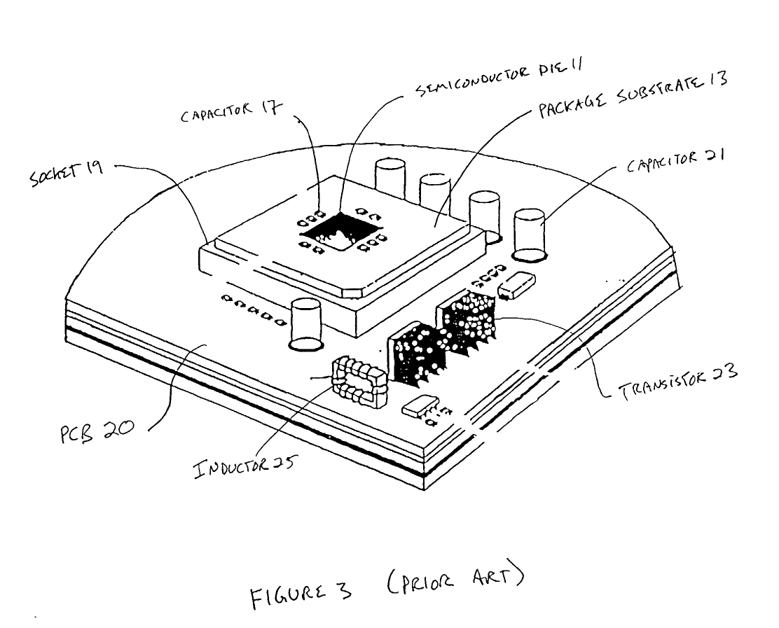

FIG. 4 is a top view of a windowframe capacitor in accordance with one embodiment of the invention;

FIG. 5 is a cross-sectional view of the embodiment of FIG. 4 taken along the lines V-V;

FIG. 6 is a bottom view of a windowframe capacitor in accordance with an embodiment of the invention;

FIG. 7 is a cross-sectional view in accordance with another embodiment of the invention; and

FIG. 8 is a cross-sectional view in accordance with another embodiment of the invention.

### DETAILED DESCRIPTION

Various exemplary embodiments of the invention will now be described with reference to the accompanying figures. Like elements are referred to by like reference numerals in the several views for the sake of clarity.

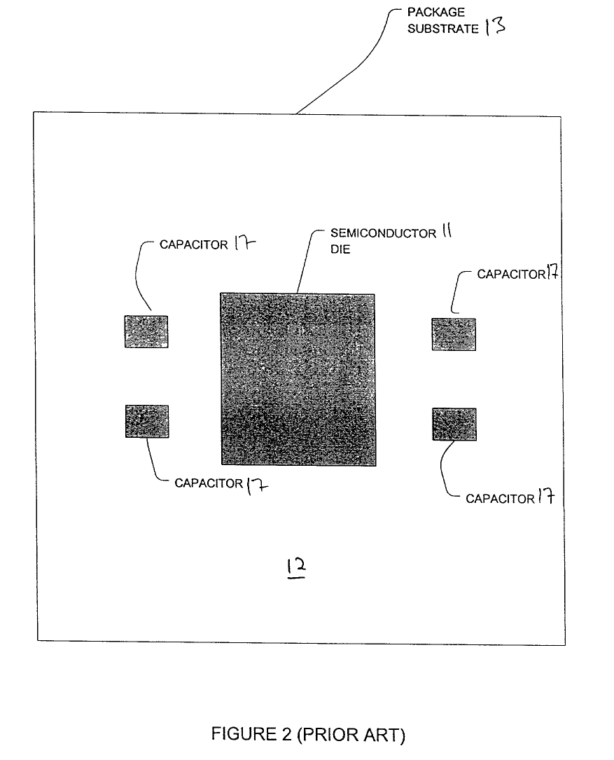

Referring back to prior art FIG. 2, it can be seen that a number of discrete capacitors 17 may be mounted on the available package surface area 12 of package substrate 13. However, there is a practical limit to the number of these capacitors 17 that may be mounted on the available surface area. In addition, as the number of individual capacitors 17 increases, so does the inductance associated with the capacitors.

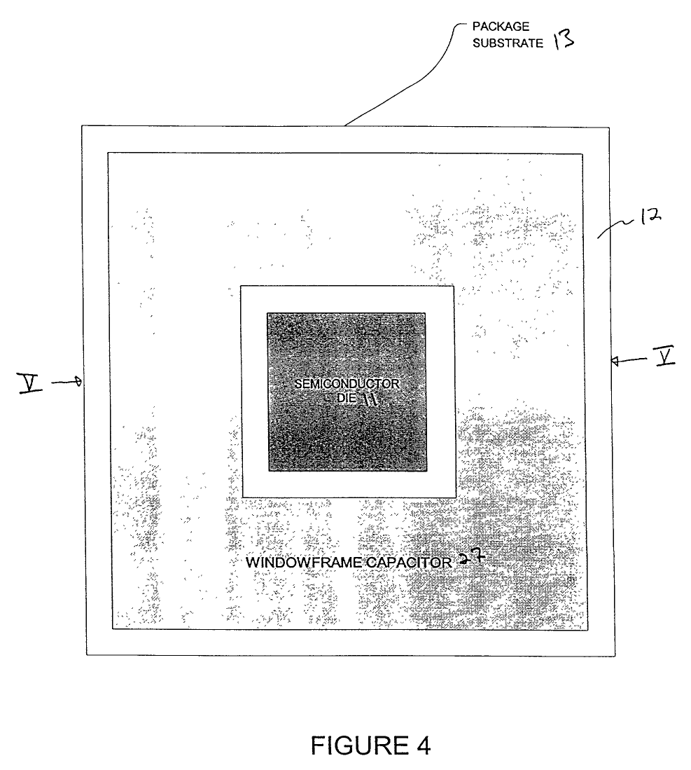

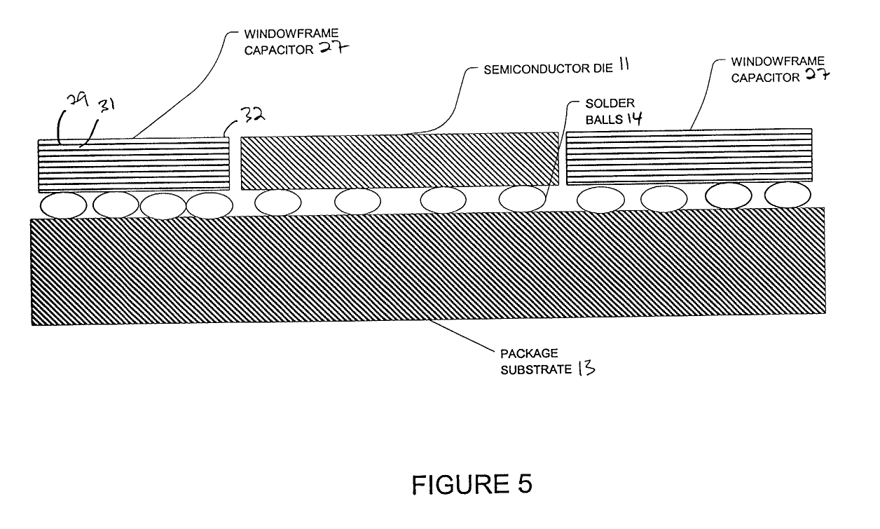

Referring now to FIG. 4, in accordance with one embodiment of the invention, a windowframe capacitor 27 is provided on the surface 12 of package substrate 13. As can be seen from the figure, the windowframe capacitor is a unitary device configured in the shape of a windowframe so as to surround semiconductor die 11 and encompass substantially the entire available surface area of package substrate 13. Shown in side view in FIG. 5, it can be seen that the windowframe capacitor 27 completely surrounds the semi-conductor die 11, and may be attached to the package substrate by, for example, a BGA configuration, or any other known configuration. The windowframe capacitor 27, in accordance with one embodiment, is constructed of a plurality of alternating layers of electrically conductive material 29 and dielectric layers 31 within a housing 32, thus increasing the overall capacitance of the device for the given surface area. The housing may be formed of plastic, or any other solid material. Alternatively, using high dielectric materials, the capacitor 27 may be formed of co-fired ceramic, which can later be integrated with or buried within the substrate 13. The choice of manner and materials of construction for the capacitor 27 will depend on the material used for the substrate 13, as well as other practical design considerations.

One of ordinary skill in the art will appreciate that, while certain specific exemplary embodiments have been disclosed, any other known configuration for formation of the adequate amount of capacitance in accordance with normal design considerations would be appropriate and within the scope of the invention. Although the windowframe capacitor 27 is shown here in the ball grid array configuration (BGA), likewise any known method of mounting the windowframe capacitor 27 to the package substrate, including but not limited to a co-fired mount, would be appropriate and within the scope of the invention.

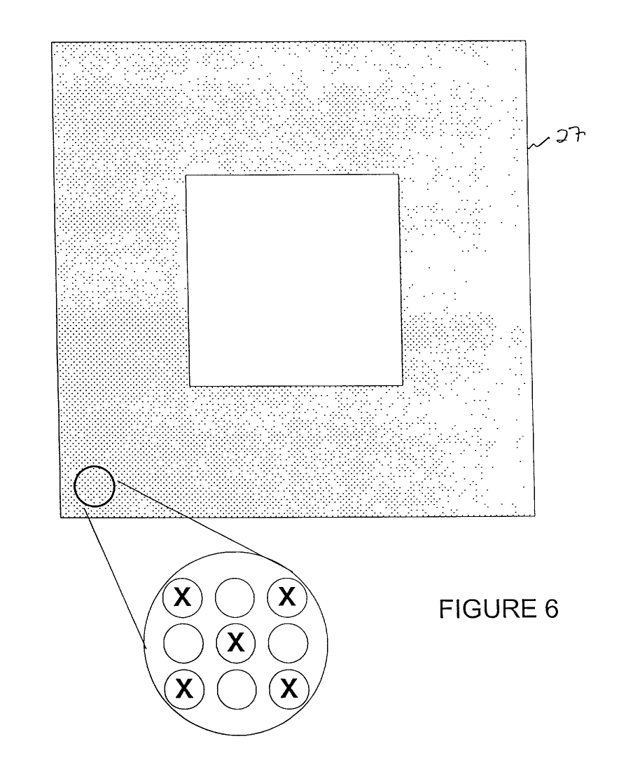

Referring now to FIG. 6, a bottom view of a windowframe capacitor 27 in accordance with an embodiment of the invention as shown. As explained previously, in actuality, the solder balls in a ball grid array are quite small relative to the size of the device. In a typical application, there would be thousands of such balls. As shown in the exploded view of FIG. 6, the solder balls are laid out in a grid array. In accordance with an embodiment of the invention, overall inductance of the windowframe capacitor may be greatly reduced by placing the Vₛₛ and V_{DD} connections in an alternating fashion throughout the array. Of course, if other grid array mounting techniques are used, a similar alternating scheme may be employed to reduce inductance. Thus, this configuration is shown for purposes of illustration and understanding only.

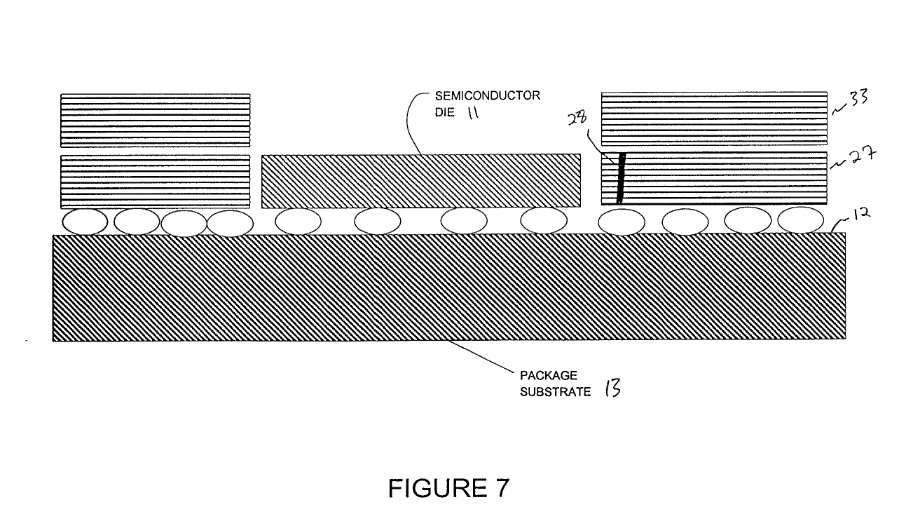

Turning now to FIG. 7, a windowframe capacitor 27 in accordance with an embodiment of the invention like that shown in FIG. 5 is shown. However, in this embodiment, a second windowframe capacitor 33 is shown mounted or stacked on top of the first windowframe capacitor 27. From this embodiment, it is clear that one advantage of the invention is that two or more windowframe capacitors in accordance with the invention may be stacked one on top of each other to further take advantage of the available surface area 12 on the top of the package substrate 13. The means of interconnecting the first and subsequent windowframe capacitors may be any known method including, for example, a ball grid array. In addition, through holes 28 (only one is shown) may be provided in the first windowframe capacitor 27 to allow electrical interconnection of the second windowframe capacitor 33 through to the package substrate 13.

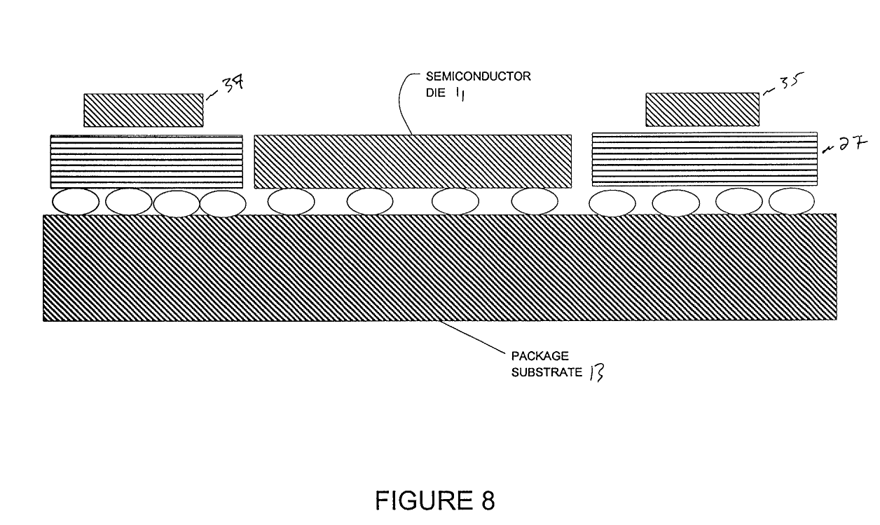

Turning now to FIG. 8, another embodiment of the invention is shown. In this embodiment, again, the windowframe capacitor 27 is shown mounted on the package substrate 13 in a BGA configuration. However, in this embodiment, it is shown that additional electronic components may be mounted on top of the windowframe capacitor 27, to further utilize the space made available by use of the windowframe capacitor. These electrical elements, shown in this figure as element 35 and element 37, may be any type of element, including, for example, discrete capacitors, voltage regulators, and the like. Thus, it is clear that one advantage of the invention is that near complete utilization of the available surface area of the package substrate 13 is achieved, while providing second and subsequent flat surface areas available for mounting of additional electronic components in accordance with desired design configurations.

Advantages of the invention include one or more of the following. In accordance with embodiments of the invention, greater utilization of the surface area of package substrate 13 may be achieved through use of the windowframe capacitor. In addition, by rendering the windowframe capacitor as a single unit, the effective capacitance may be increased, while the inductance may be decreased versus the use of a multitude of individual high frequency capacitors. Furthermore, because of the physical nature of the windowframe capacitor, the top area of the windowframe capacitor remains available for mounting of additional windowframe capacitors or other electronic components.

While the invention has been described with respect to a limited number of exemplary embodiments, the invention is not so limited. Persons of ordinary skill in the art will recognize that various modifications and alternatives to the embodiments shown may be made in accordance with desired design specifications without departing from the scope of the invention. Accordingly, the invention shall be considered limited only by the scope of the appended claims.

What is claimed is:

1. A windowframe capacitor, comprising:
a housing having a bottom surface and a top surface, wherein an aperture is formed in a central portion thereof extending from the top surface to the bottom surface; and
capacitive material disposed within the housing to create a desired amount of capacitance;
wherein the bottom surface is provided with electrical connections adapted to be connected to a substrate.

2. The windowframe capacitor of claim 1, wherein the aperture is rectangular.

3. The windowframe capacitor of claim 1, wherein the capacitive material comprises a layer of an electrically conductive material and a layer of a dielectric material.

4. The windowframe capacitor of claim 3, wherein the housing is made from a plastic material.

5. The windowframe capacitor of claim 1, wherein said electrical connections provided on the bottom surface comprise a ball grid array.

6. The windowframe capacitor of claim 1, wherein the capacitive material and the housing comprise co-fired ceramic.

7. The windowframe capacitor of claim 1, wherein the aperture is configured to fit over a semiconductor die, and wherein said electrical connections are configured for connection to a package substrate on which the semiconductor die is mounted.

8. A semiconductor package assembly, comprising:
a semiconductor die mounted on a portion of a top surface of a package substrate; and
a windowframe capacitor having an aperture formed therein, and mounted on the top surface of the package substrate surrounding the semiconductor die.

9. The semiconductor package assembly of claim 8, further comprising an electronic component mounted on a top surface of the windowframe capacitor.

10. The semiconductor package assembly of claim 8, further comprising a second windowframe capacitor mounted on a top surface of the first windowframe capacitor.

11. The semiconductor package assembly of claim 8, wherein the aperture is rectangular.

12. The semiconductor package assembly of claim 8, wherein the windowframe capacitor comprises a housing.

13. The semiconductor package assembly of claim 12, wherein the windowframe capacitor comprises a capacitive material disposed within the housing.

14. The semiconductor package assembly of claim 13, wherein the capacitive material comprises a layer of an electrically conductive material and a layer of a dielectric material.

15. The semiconductor package assembly of claim 14, wherein the housing is made of a plastic material.

16. The semiconductor package assembly of claim 13, wherein the capacitive material and the housing comprise a co-fired ceramic.

17. The semiconductor package assembly of claim 8, wherein the windowframe capacitor is mounted on the package substrate via a ball grid array.
